(19) United States
(12) Patent Application Publication
(10) Pub. No.: US 2026/0156962 A1
(43) Pub. Date: Jun. 4, 2026

(54) LINEAR TOOL AND METHOD FOR PARALLEL METALLIZATION OF SOLAR CELL SUBSTRATES

(71) Applicant: Applied Materials Italia S.R.L., San Biagio di Callalta (IT)

(72) Inventors: Davide COLLA, Treviso (IT); Alessandro VOLTAN, Morgano (IT); Marco GALIAZZO, Quinto di Treviso (IT); Alberto Emilio RUFFO, Casale Sul Sile (IT); Daniele ANDREOLA, Treviso (IT)

(21) Appl. No.: 19/293,432

(22) Filed: Aug. 7, 2025

(30) Foreign Application Priority Data
Dec. 3, 2024 (IT) 102024000027360

(51) Int. Cl. H10F 71/00; B65G 17/12

(52) U.S. Cl. CPC H10F 71/1375; B65G 17/12

(57) ABSTRACT

A linear tool for parallel metallization of solar cell substrates is provided. The linear tool includes an alignment system for adjusting a relative position of the first and second solar cell substrate. The linear tool includes a first inspection system for inspecting at least one of the first and second solar cell substrate while the first and second solar cell substrate are held by the alignment system. The linear tool includes a shuttle platform for jointly supporting the first and second solar cell substrate. The shuttle platform is movable from a loading position to a printing position. The linear tool is configured to transfer the first and second solar cell substrate from the alignment system to the shuttle platform when the shuttle platform is in the loading position. The linear tool includes a screen printer configured for parallel metallization of the first and second solar cell substrate.

### TECHNICAL FIELD

Embodiments described herein relate to tools for performing metallization of solar cell substrates. More specifically, embodiments described herein relate to tools that involve a printer for printing a conductive pattern, such as a pattern of fingers and busbars, on a solar cell substrate to perform the metallization. Embodiments described herein also relate to methods for performing metallization of solar cell substrates.

### BACKGROUND

Solar cells are photovoltaic devices that convert sunlight directly into electrical power. Within the field of solar cells, it is known to produce solar cells from a crystalline silicon substrate using deposition techniques, particularly printing techniques, achieving, for example on the front surface of the solar cells, a structure of selective emitters.

More specifically, for manufacturing a solar cell, a conductive pattern of fingers and busbars can be printed on the substrate using a screen printer. The substrate is typically a substantially square silicon wafer. The screen printer has a screen with a pattern of openings corresponding to the pattern of fingers and/or busbars that is to be printed on the substrate. A squeegee may move over the screen to perform a printing stroke, whereby a conductive paste, e.g. a silver paste, is urged though the openings in the screen to form the pattern of fingers and/or busbars. After the printing, a quality control may be performed by inspecting the solar cell.

There is a continuous need for improving the tools and processes for manufacturing solar cells, in particular the tools and processes for printing the fingers and busbars on a substrate, for example as regards throughput, footprint, cycle time and the like.

### SUMMARY

According to an embodiment, a linear tool for parallel metallization of solar cell substrates is provided. The linear tool includes an alignment system for jointly holding a first solar cell substrate and a second solar cell substrate and for adjusting a relative position of the first solar cell substrate and the second solar cell substrate. The linear tool includes a first inspection system arranged for inspecting at least one of the first solar cell substrate and the second solar cell substrate while the first solar cell substrate and the second solar cell substrate are held by the alignment system. The linear tool includes a shuttle system including a shuttle platform for jointly supporting the first solar cell substrate and the second solar cell substrate. The shuttle platform is movable from a loading position to a printing position. The linear tool is configured to transfer the first solar cell substrate and the second solar cell substrate from the alignment system to the shuttle platform when the shuttle platform is in the loading position. The linear tool includes a screen printer comprising a screen facing the shuttle platform when the shuttle platform is in the printing position. The screen printer is configured for parallel metallization of the first solar cell substrate and the second solar cell substrate supported by the shuttle platform when the shuttle platform is in the printing position. The shuttle platform is movable from the printing position to an unloading position for unloading the first solar cell substrate and the second solar cell substrate from the shuttle platform.

According to a further embodiment, a method for parallel metallization of solar cell substrates is provided. The method includes jointly holding a first solar cell substrate and a second solar cell substrate using an alignment system. The method includes inspecting at least one of the first solar cell substrate and the second solar cell substrate while the first solar cell substrate and the second solar cell substrate are held by the alignment system. The method includes, in response to the inspecting, adjusting a relative position of the first solar cell substrate and the second solar cell substrate using the alignment system. The method includes transferring the first solar cell substrate and the second solar cell substrate from the alignment system to a shuttle platform of a shuttle system when the shuttle platform is in a loading position. The method includes moving the shuttle platform supporting the first solar cell substrate and the second solar cell substrate from the loading position to a printing position. The method includes performing a parallel metallization of the first solar cell substrate and the second solar cell substrate supported by the shuttle platform when the shuttle platform is in the printing position, wherein the parallel metallization is performed by a screen printer. The method includes moving the shuttle platform supporting the first solar cell substrate and the second solar cell substrate from the printing position to an unloading position. The method includes unloading the first solar cell substrate and the second solar cell substrate from the shuttle platform in the unloading position.

Embodiments are also directed to apparatuses for carrying out the disclosed methods and include apparatus parts for performing each described method aspect. The method aspects may be performed by way of hardware components, a computer programmed by appropriate software, by any combination of the two or in any other manner. Furthermore, embodiments according to the disclosure are also directed to methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1-6 illustrate a sequence of operations performed by a first linear tool for performing parallel metallization of two solar cell substrates;

FIGS. 7-12 illustrate a sequence of operations performed by a second linear tool for performing parallel metallization of two solar cell substrates;

FIG. 13 shows a linear tool for parallel metallization of solar cell substrates;

FIG. 14-15 show a telescopic belt conveyer;

FIG. 16 shows an example of a shuttle system including a conveyer assembly; and

FIG. 17 shows the conveyer assembly being transported from a loading position to an unloading position via a printing position.

### DETAILED DESCRIPTION

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Embodiments described herein relate to tools and methods for performing parallel metallization of multiple solar cell substrates. In particular, the tools and methods described herein are designed to process and metallize several half-cut solar cell substrates in parallel. The productivity is increased as compared to systems that only process half-cut substrates one at a time. Further advantages are described below.

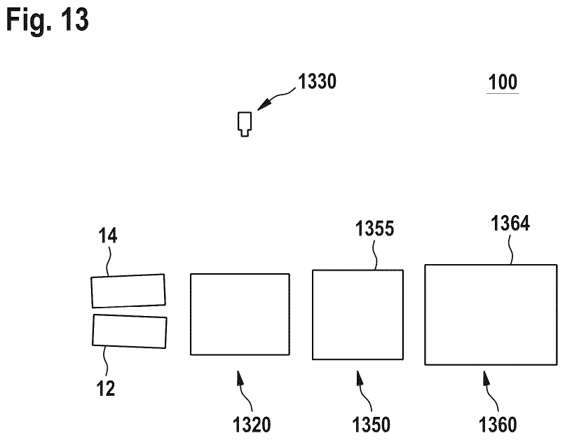

Aspects of the present disclosure are described with respect to FIG. 13 showing a linear tool 100 for parallel metallization of solar cell substrates. The linear tool 100 includes an alignment system 1320 for jointly holding a first solar cell substrate 12 and a second solar cell substrate 14 and for adjusting a relative position of the first solar cell substrate 12 and the second solar cell substrate 14. The linear tool 100 includes a first inspection system 1330 arranged for inspecting at least one of the first solar cell substrate 12 and the second solar cell substrate 14 while the first solar cell substrate 12 and the second solar cell substrate 14 are held by the alignment system 1320. The linear tool 100 includes a shuttle system 1350 including a shuttle platform 1355 for jointly supporting the first solar cell substrate 12 and the second solar cell substrate 14. The shuttle platform 1355 is movable from a loading position to a printing position. The linear tool 100 is configured to transfer the first solar cell substrate 12 and the second solar cell substrate 14 from the alignment system 1320 to the shuttle platform 1355 when the shuttle platform 1355 is in the loading position. The linear tool 100 includes a screen printer 1360 including a screen 1364 facing the shuttle platform 1355 when the shuttle platform 1355 is in the printing position. The screen printer 1360 is configured for parallel metallization of the first solar cell substrate 12 and the second solar cell substrate 14 supported by the shuttle platform 1355 when the shuttle platform 1355 is in the printing position. The shuttle platform 1355 is movable from the printing position to an unloading position for unloading the first solar cell substrate 12 and the second solar cell substrate 14 from the shuttle platform.

A linear tool, as described herein, is distinguished from a rotary tool, such as a rotary tool where solar cell substrates are processed on a rotary table. A linear tool may have an input end (e.g. on the left-hand side in FIG. 13) and an output end (e.g. on the right-hand side in FIG. 13). The input end and the output end may be opposing ends of the linear tool 100. A solar cell substrate may be received by the linear tool 100 at the input end. After the linear tool 100 has completed the processing of the solar cell substrate, the solar cell substrate may be discharged from the linear tool 100 at the output end. The input end and the output end may be separated from each other by one or more systems, or processing stations, comprised in the linear tool, such as at least one of the alignment system 1320, the shuttle system 1350 and the screen printer 1360. The one or more systems may include a plurality of systems arranged according to a linear arrangement from the input end to the output end. The linear arrangement may be one-dimensional, or line-shaped. A linear tool may be free of a rotary support for transporting the solar cell substrates along the systems (processing stations) comprised in the linear tool.

A solar cell substrate, such as the first solar cell substrate 12 or the second solar cell substrate 14, or any other solar cell substrate described herein, can be understood as a substrate used for the manufacture of a solar cell. A solar cell substrate can be a flat piece of material, e.g. a wafer. A solar cell substrate can be made of a semiconductor material, e.g. silicon, or any other material suitable for manufacturing solar cells.

A solar cell substrate, such as the first solar cell substrate 12 or the second solar cell substrate 14, or any other solar cell substrate described herein, can have a length and a width. The width may be smaller than the length. The width may be about one half of the length (where the term “about” includes a deviation of at most 15%). The solar cell substrate may have a rectangular shape. A solar cell substrate may be a half-cut solar cell substrate. A half-cut solar cell substrate refers to a rectangular solar cell substrate obtained by cutting a square solar cell substrate in half.

The first solar cell substrate 12 may have a first length and a first width, the first width being about one half of the first length. The second solar cell substrate 14 may have a second length and a second width, the second width being about one half of the second length. Therein, the term “about” includes a deviation of at most 15% of a first/second width being exactly one half of the first/second length.

The process of metallization of a solar cell substrate, which is performed by the screen printer 1360, can be understood as the printing of one or more conductive patterns, also called conductive contacts, on the solar cell substrate. The one or more conductive patterns may be configured for collecting and/or transporting electrical current generated by the solar cell substrate. The electrical current may be obtained from the conversion of light into electrical energy by the solar cell substrate. The one or more conductive patterns may include one or more fingers and/or one or more busbars.

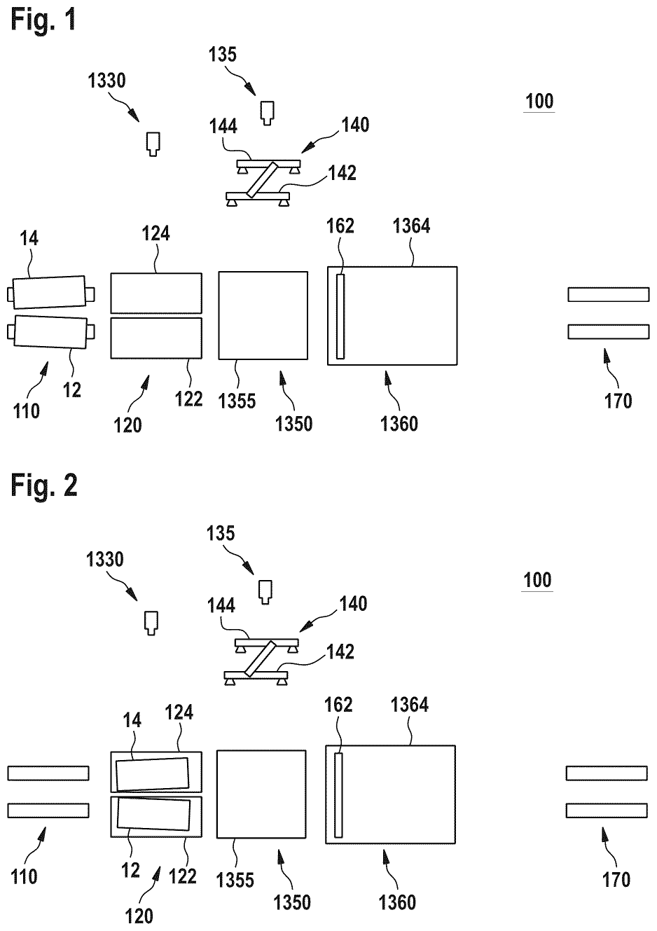

As discussed below with respect to FIGS. 1-6, the alignment system of a linear tool may include a first alignment platform for supporting the first solar cell substrate, and a second alignment platform for supporting the second solar cell substrate. A relative position of the first alignment platform and the second alignment platform may be adjustable to adjust the relative position of the first solar cell substrate and the second solar cell substrate. The first inspection system may be arranged for inspecting at least one of the first solar cell substrate supported by the first alignment platform and the second solar cell substrate supported by the second alignment platform. The linear tool may include a pick and place system arranged for jointly transferring the first solar cell substrate and the second solar cell substrate from the alignment system to the shuttle system. The pick and place system may be arranged for placing the first solar cell substrate and the second solar cell substrate on the shuttle platform when the shuttle platform is in the loading position.

FIGS. 1-6 show a linear tool 100 for performing parallel metallization of a first solar cell substrate 12 and a second solar cell substrate 14.

In FIG. 1, the first solar cell substrate 12 and the second solar cell substrate 14 are supported by a support 110, which may be a conveyer system.

The first solar cell substrate 12 and the second solar cell substrate 14 may be transferred, e.g. using a pick and place system, from the support 110 to an alignment system 120. The pick and place system may include a gripper configured for holding the first solar cell substrate 12 and the second solar cell substrate 14 jointly, so that the first solar cell substrate 12 and the second solar cell substrate 14 may be transferred together from the support 110 to the alignment system 120.

The alignment system 120 in FIGS. 1-6 is a possible example of the alignment system 1320 in FIG. 13. The alignment system 120 may include first alignment platform 122 and a second alignment platform 124. The first solar cell substrate 12 and the second solar cell substrate 14 may be transferred from the support 110 to the first alignment platform 122 and the second alignment platform 124, respectively, for example using the aforementioned pick and place system. FIG. 2 shows the first alignment platform 122 supporting the first solar cell substrate 12 and the second alignment platform 124 supporting the second solar cell substrate 14.

The alignment system 120 may include precisely two alignment platforms, being the first alignment platform 122 and the second alignment platform 124. The two alignment platforms may each be configured for supporting a half-cut solar cell substrate, so that precisely two half-cut solar cell substrates, which have a joint area corresponding to the area of one full square solar cell, are held by the alignment system 120. The first alignment platform 122 may have a first receiving area for receiving the first solar cell substrate 12 and the second alignment platform 124 may have a second receiving area for receiving the second solar cell substrate 14. The first receiving area may have a first length and a first width, the first width being about one half of the first length (with a deviation of up to 15%). The second receiving area may have a second length and a second width, the second width being about one half of the second length (with a deviation of about 15%). A receiving area of an alignment platform, such as the first/second receiving area, may be an area corresponding to the area of a solar cell substrate, particularly a half-cut solar cell substrate, supported by the alignment platform.

A “platform” for supporting a solar cell substrate, such as the first alignment platform 122, the second alignment platform 124 or the shuttle platform 1355 described below, is distinguished from a gripper for holding a solar cell substrate. A platform is configured for supporting a solar cell substrate on top of the platform. The solar cell substrate may be disposed on top of a substantially flat receiving surface of the platform. The platform may contact a bottom substrate of the solar cell substrate. A top surface of a solar cell substrate supported by a platform can be processed by a processing device. For example, a solar cell substrate supported by a platform can be subject to a deposition process e.g. a printing process. In comparison, a gripper can be understood as a movable member which may be configured for facing a platform on which one or more solar cell substrates are disposed. A gripper may be part of a pick and place system. A gripper may be configured for picking up, i.e. lifting, a solar cell substrate from the platform. A top surface of a solar cell substrate may be gripped by the gripper, particularly by a bottom surface of the gripper.

At least one of the first alignment platform 122 and the second alignment platform 124 may be movable to adjust a relative position of the first solar cell substrate 12 supported by the first alignment platform 122 and the second solar cell substrate 14 supported by the second alignment platform 124. The alignment system 120 may include an actuator system including one or more actuators, e.g. one or more motors, for moving at least one of the first alignment platform 122 and the second alignment platform 124.

The first alignment platform 122 may be movable in at least one of a first horizontal direction, a second horizontal direction different from (e.g. perpendicular to) the first horizontal direction, and an angular direction. The movement in an angular direction may include an angular movement with respect to a rotation axis perpendicular to the first alignment platform 122. By performing one or more of the aforementioned movements, the first alignment platform 122 may adjust a position of the first solar cell substrate 12. The first alignment platform 122 may be movable according to one or more of the aforementioned movements relative to the second alignment platform 124 to adjust a relative position of the first solar cell substrate 12 with respect to the second solar cell substrate 14. The first alignment platform 122 may be individually movable, independently of the second alignment platform 124.

Additionally, or alternatively, the second alignment platform 124 may be movable in at least one of a first horizontal direction, a second horizontal direction different from (e.g. perpendicular to) the first horizontal direction, and an angular direction. Said first direction and/or second horizontal direction may be the same as the first direction and/or second horizontal direction, respectively, described above in relation to the first alignment platform 122. The movement in an angular direction may include an angular movement with respect to a rotation axis perpendicular to the second alignment platform 124. By performing one or more of the aforementioned movements, the second alignment platform 124 may adjust a position of the second solar cell substrate 14. The second alignment platform 124 may be movable according to one or more of the aforementioned movements relative to the first alignment platform 122 to adjust a relative position of the second solar cell substrate 14 with respect to the first solar cell substrate 12. The second alignment platform 124 may be individually movable, independently of the first alignment platform 122.

The first inspection system 1330 may be arranged for inspecting at least one of the first solar cell substrate 12 supported by the first alignment platform 122 and the second solar cell substrate 14 supported by the second alignment platform 124. The first inspection system 1330 may be an optical inspection system. The first inspection system 1330 may include one or more cameras. The first inspection system 1330 may be configured to make an image of at least one of the first solar cell substrate 12 supported by the first alignment platform 122 and the second solar cell substrate 14 supported by the second alignment platform 124. An alignment of the first solar cell substrate 12 and/or the second solar cell substrate 14 may be performed by the alignment system 120 based on inspection data, e.g. the mentioned image, provided by the first inspection system 1330.

The linear tool 100 may include a controller. The controller may be connected to the first inspection system 1330. The controller may be connected to the alignment system 120. The controller may instruct the first inspection system 1330 to perform a first inspection of at least one of the first solar cell substrate 12 supported by the first alignment platform 122 and the second solar cell substrate 14 supported by the second alignment platform 124. The controller may instruct the alignment system 120 to adjust a relative position of the first alignment platform 122 supporting the first solar cell substrate 12 and the second alignment platform 124 supporting the second solar cell substrate 14 in response to the first inspection. Adjusting a relative position of the first alignment platform 122 and the second alignment platform 124 may include moving the first alignment platform 122, moving the second alignment platform 124 or moving both the first alignment platform 122 and the second alignment platform 124.

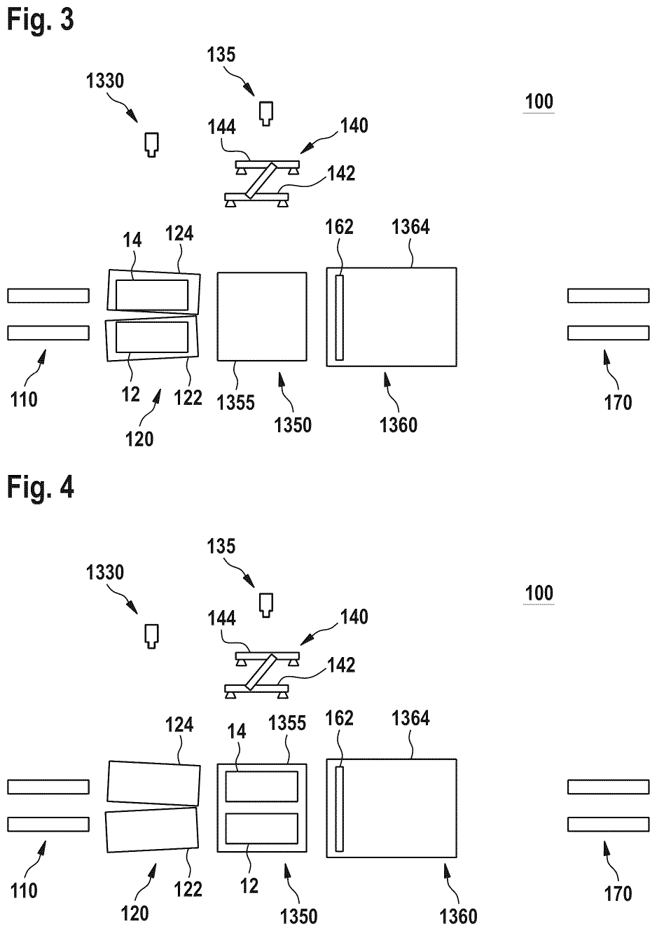

As illustrated in FIG. 2, after the first solar cell substrate 12 and the second solar cell substrate 14 have been transferred to the alignment system, it may be the case that the first solar cell substrate 12 supported by the first alignment platform 122 and/or the second solar cell substrate 14 supported by the second alignment platform 124 are misaligned. A misalignment may exist, for example, if the respective edges of the two solar cell substrates are not parallel to each other (as illustrated in an exaggerated manner in FIG. 2), if a misalignment exists with respect to one or more alignment marks, and the like. Based on the inspection performed by the first inspection system 1330, e.g. an image taken by the first inspection system 1330, the alignment system 120 can move at least one of the first alignment platform 122 and the second alignment platform 124 to provide the first solar cell substrate 12 and the second solar cell substrate 14 in an aligned configuration (with respect to each other, with respect to one or more alignment marks, or the like). An aligned configuration is illustrated in FIG. 3, showing the first solar cell substrate 12 and the second solar cell substrate 14 in an exemplary configuration where the edges thereof are parallel to each other.

FIG. 4 shows the shuttle platform 1355 of the shuttle system 1350 in the loading position of the shuttle platform 1355. The shuttle platform 1355 may move into the loading position, for example, while the first solar cell substrate 12 and the second solar cell substrate 14 are supported by the alignment system 120. The shuttle system 1350 may be controlled by the controller.

The linear tool 100 may include a pick and place system 140 arranged for jointly transferring the first solar cell substrate 12 and the second solar cell substrate 14 from the alignment system 120 to the shuttle system 1350, particularly after the first solar cell substrate 12 and the second solar cell substrate 14 have been provided in an aligned configuration by the alignment system 120. The pick and place system 140 may be arranged for placing the first solar cell substrate 12 and the second solar cell substrate 14 on the shuttle platform 1355 when the shuttle platform 1355 is in the loading position. The pick and place system 140 may include a gripper system for jointly holding the first solar cell substrate 12 and the second solar cell substrate 14. The pick and place system 140 may include a first gripper portion 142 for holding the first solar cell substrate 12 and a second gripper portion 144 for holding the second solar cell substrate 14. The pick and place system 140 may be controlled by the controller.

The pick and place system 140 may be configured to maintain the relative position of the first solar cell substrate 12 and the second solar cell substrate 14 while transferring the first solar cell substrate 12 and the second solar cell substrate 14 from the alignment system 120 to the shuttle platform 1355. The pick and place system 140 may maintain the aligned configuration of the first solar cell substrate 12 and the second solar cell substrate 14 provided by the alignment system 120. The first solar cell substrate 12 and the second solar cell substrate 14 supported by the shuttle platform 1355 may still be in the aligned configuration, as illustrated in FIG. 4.

The linear tool 100 may optionally include a second inspection system 135 arranged for inspecting at least one of the first solar cell substrate 12 and the second solar cell substrate 14 supported by the shuttle platform 1355, for example when the shuttle platform 1355 is in the loading position (as illustrated in FIG. 4). The second inspection system 135 may be an optical inspection system and may, for example, include one or more cameras. The second inspection system 135 may be controlled by the controller. The second inspection system 135 may optionally be configured to detect a possible misalignment of the first solar cell substrate 12 and the second solar cell substrate 14 supported by the shuttle platform 1355. As described above, a misalignment may exist, for example, if the respective edges of the first solar cell substrate 12 and the second solar cell substrate 14 are not parallel to each other and/or if the first solar cell substrate and/or the second solar cell substrate are misaligned with respect to one or more alignment marks. The misalignment may have been introduced, for example, while handling the first solar cell substrate 12 and the second solar cell substrate 14 using the pick and place system 140. If a misalignment is detected by the second inspection system 135, the first solar cell substrate 12 and/or the second solar cell substrate 14 may be discarded, under the control of the controller, from the linear tool 100 or may be returned to the alignment system 120 for a further alignment operation. If no misalignment is detected, the processing of the first solar cell substrate 12 and the second solar cell substrate 14 by the linear tool 100 may continue. In particular, the first solar cell substrate 12 and the second solar cell substrate 14 may be transported to the screen printer 1360 for metallization.

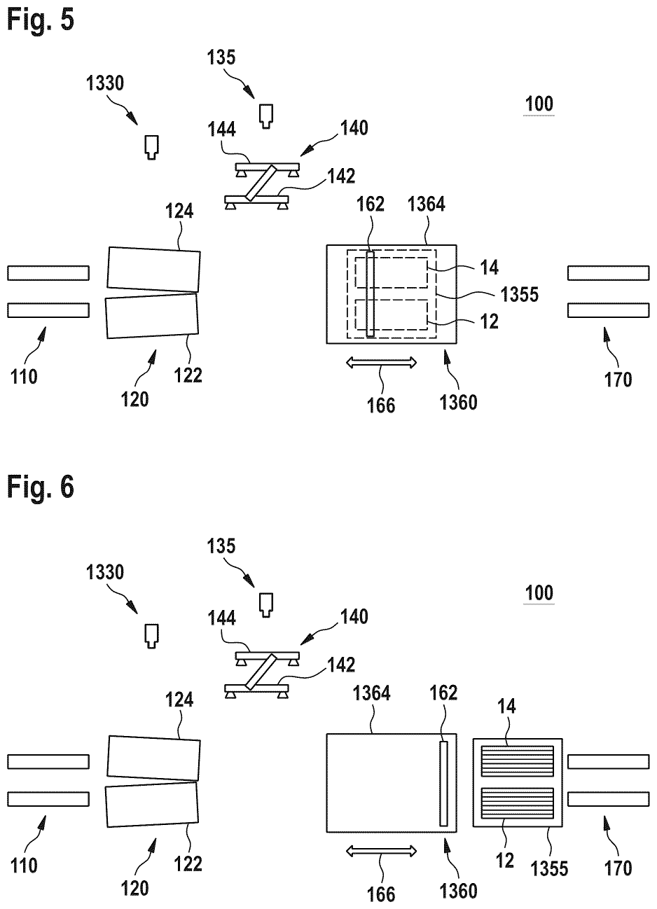

The shuttle platform 1355 supporting the first solar cell substrate 12 and the second solar cell substrate 14 may be moved, e.g. under the control of the controller, from the loading position to a printing position, particularly after an optional inspection by the second inspection system 135 has taken place. FIG. 5 shows the shuttle platform 1355 in the printing position. The shuttle system may include an actuator system including one or more actuators, e.g. one or more motors, for moving the shuttle platform 1355 from the loading position to the printing position. The printing position may be separated from the loading position by a horizontal distance. The movement of the shuttle platform 1355 from the loading position to the printing position may be a linear movement. Moving the shuttle platform 1355 from the loading position to the printing position may result in a region between the alignment system 120 and the screen printer 1360 being vacated, as illustrated in FIG. 5.

In the printing position, the shuttle platform 1355 may face the screen 1364 of the screen printer 1360. In the printing position, the first solar cell substrate 12 and the second solar cell substrate 14 supported by the shuttle platform 1355 may be disposed below the screen 1364. The first solar cell substrate 12 and the second solar cell substrate 14 supported by the shuttle platform 1355 may face the screen 1364, i.e. the same screen. The screen printer 1360 performs a parallel metallization of the first solar cell substrate 12 and the first solar cell substrate 12 supported by the shuttle platform 1355 while the shuttle platform 1355 is in the printing position. The parallel metallization may include that the first solar cell substrate 12 and the second solar cell substrate 14 are metallized simultaneously. The parallel metallization may include that a first conductive pattern, e.g. a first pattern including one or more first fingers and/or one or more first busbars, and a second conductive pattern, e.g. a second pattern including one or more second fingers and/or one or more second busbars, are printed in parallel on the first solar cell substrate 12 and the second solar cell substrate 14.

The screen printer 1360 may include a squeegee 162 configured to urge a printing material, e.g. a printing paste such as a silver paste, through openings in the screen 1364 to perform the parallel metallization of the first solar cell substrate 12 and the second solar cell substrate 14. To perform the parallel metallization, the squeegee may move over the screen 1364 in a printing direction 166. Within a same stroke of the squeegee 162 in the printing direction 166 over the screen 1364, at least a portion of a conductive pattern may be printed on both the first solar cell substrate 12 and the second solar cell substrate 14. The printing direction 166 may be a two-sided direction, indicated in FIG. 5 by the double-sided arrow. The squeegee 162 may move forward and/or backward over the screen 1364 along the printing direction 166 to perform the parallel metallization of the first solar cell substrate 12 and the second solar cell substrate 14. The operation of the screen printer 1360 may be controlled by the controller.

The printing direction 166 may correspond to a length direction of the first solar cell substrate 12 supported by the shuttle platform 1355 in the printing position, particularly if the first solar cell substrate 12 has a rectangular shape, such as a half-cut solar cell substrate. Additionally, or alternatively, the printing direction 166 may correspond to a length direction of the second solar cell substrate 14 supported by the shuttle platform 1355 in the printing position, particularly if the second solar cell substrate 14 has a rectangular shape, such as a half-cut solar cell substrate. A length direction of the first/second solar cell substrate may be a direction defined by an edge of the first/second solar cell substrate, particularly an edge along a longest dimension of the first/second solar cell substrate. The squeegee 162 may have a length extending in a direction substantially perpendicular (e.g. up to a deviation of 15% from exact perpendicularity) to the printing direction 166.

The screen printer may define a printing direction for performing the parallel metallization of the first solar cell substrate and the second solar cell substrate. The printing direction may correspond to a length direction of the first solar cell substrate and the second solar cell substrate supported by the shuttle platform in the printing position.

After the parallel metallization of the first solar cell substrate 12 and the second solar cell substrate 14, the shuttle platform 1355 supporting the first solar cell substrate 12 and the second solar cell substrate 14 may be moved, e.g. by the actuator system of the shuttle system, from the printing position to the unloading position, e.g. under the control of the controller. FIG. 6 shows the shuttle platform 1355 supporting the metallized first solar cell substrate 12 and the metallized second solar cell substrate 14 in the unloading position. The unloading position may be separated from the printing position by a horizontal distance. The movement of the shuttle platform 1355 from the printing position to the unloading position may be a linear movement. Moving the shuttle platform 1355 from the printing position to the unloading position may result in a region below the screen 1364 being vacated by the shuttle platform 1355.

In the unloading position, the shuttle platform 1355 may be adjacent to a transportation system 170, e.g. a conveyer system. The linear tool 100 may be configured for transferring the metallized first solar cell substrate 12 and the metallized second solar cell substrate 14 from the shuttle platform 1355 to the transportation system 170. After the metallized first solar cell substrate 12 and the metallized second solar cell substrate 14 have been unloaded from the shuttle platform 1355 (e.g. transferred to the transportation system 170), the shuttle platform 1355 may be moved from the unloading position to the loading position, e.g. under the control of the controller. In the loading position, the shuttle platform 1355 may receive a third solar cell substrate and a fourth solar cell substrate from the pick and place system 140 after the third solar cell substrate and the fourth solar cell substrate have been aligned by the alignment system 120. The third solar cell substrate and the fourth solar cell substrate may be processed by the linear tool 100 similar to the first solar cell substrate 12 and the second solar cell substrate 14.

The shuttle platform 1355 may be configured to move from the loading position to the printing position, from the printing to the unloading position and from the unloading position to the loading position. The shuttle platform 1355 may be configured to move from the loading position to the printing position and/or to move from the printing position to the unloading position while the first solar cell substrate 12 and the second solar cell substrate 14 are supported by the shuttle platform 1355. The shuttle platform 1355 may be configured to move from the unloading position to the loading position after the first solar cell substrate 12 and the second solar cell substrate 14 have been unloaded from the shuttle platform 1355. The aforementioned movements of the shuttle platform 1355 may be controlled by the controller.

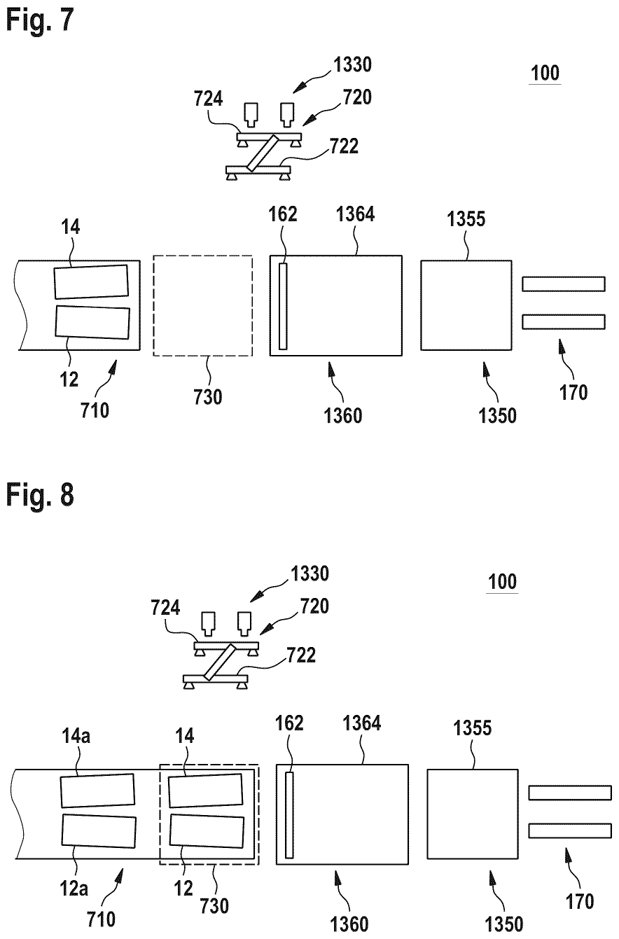

As described below with respect to FIGS. 7-12, a linear tool may include a transportation system for jointly transporting the first solar cell substrate and the second solar cell substrate. The transportation system may be arranged to move the first solar cell substrate and the second solar cell substrate into a transfer area. The alignment system may include a gripper system for picking up the first solar cell substrate and the second solar cell substrate from the transportation system when the first solar cell substrate and the second solar cell substrate are in the transfer area. The gripper system may include a first gripper section for holding the first solar cell substrate and a second gripper section for holding the second solar cell substrate. A relative position of the first gripper section and the second gripper section may be adjustable to adjust the relative position of the first solar cell substrate and the second solar cell substrate. The first inspection system may be arranged for inspecting at least one of the first solar cell substrate held by the first gripper section and the second solar cell substrate held by the second gripper section. The loading position of the shuttle platform may be in the transfer area. The gripper system may be arranged for placing the first solar cell substrate and the second solar cell substrate on the shuttle platform when the shuttle platform is in the loading position in the transfer area.

FIGS. 7-12 show a linear tool 100 for performing parallel metallization of a first solar cell substrate 12 and a second solar cell substrate 14. Some of the components of the linear tool 100 shown in FIGS. 7-12 (“second linear tool”), such as the shuttle system 1350 and the screen printer 1360, are also included in the linear tool 100 shown in FIGS. 1-6 (“first linear tool”). Unless stated otherwise, the properties and functions of such common components are the same in both linear tools, and the description thereof provided above with respect to the first linear tool also applies to the second linear tool.

As shown in FIG. 7, the linear tool 100 may include a transportation system 710 for jointly transporting the first solar cell substrate 12 and the second solar cell substrate 14. The transportation system 710 may support the first solar cell substrate 12 and the second solar cell substrate 14 from below, so that the transportation system 710 supports a bottom surface of the first solar cell substrate 12 and a bottom surface of the second solar cell substrate 14. The transportation system 710 may, for example, be a conveyer system including one or more belt conveyers. The first solar cell substrate 12 and the second solar cell substrate 14 may be disposed side by side on the transportation system 710.

It may be the case that the first solar cell substrate 12 and the second solar cell substrate 14, while supported by the transportation system 710, are not properly aligned. For example, the long edges of the first solar cell substrate 12 and the second solar cell substrate 14 may be non-parallel to each other.

The linear tool 100 may include a transfer area 730. The transfer area 730 may be disposed between an end of the transportation system 710 and the screen printer 1360. The transfer area 730 may have dimensions suitable to receive the shuttle platform 1355 within the transfer area 730. FIG. 7 shows the transfer area 730 in a vacated state. In particular, the transportation system 710 and the shuttle platform 1355 are outside of the transfer area 730.

As illustrated in FIG. 8, the transportation system 710 may be arranged to move the first solar cell substrate 12 and the second solar cell substrate 14 into the transfer area 730. The transportation system 710 may include a portion supporting the first solar cell substrate 12 and the second solar cell substrate 14. Said portion may be moved into the transfer area 730, so that the first solar cell substrate 12 and the second solar cell substrate 14 supported by the transportation system 710 are disposed in the transfer area 730, as illustrated in FIG. 8. For example, the transportation system 710 may include a telescopic belt conveyer that can be moved into and out of the transfer area 730, as described below. A telescopic belt conveyer is only one possible example, and it shall be appreciated that any transportation system capable of moving the solar cell substrates into the transfer area 730 can be considered.

As illustrated in FIG. 8, when the first solar cell substrate 12 and the second solar cell substrate 14 supported by the transportation system 710 are in the transfer area 730, a third solar cell substrate 12a and a fourth solar cell substrate 14a may be supported by the transportation system 710 behind the first solar cell substrate 12 and the second solar cell substrate 14. The third solar cell substrate 12a and the fourth solar cell substrate 14a may be processed by the linear tool 100, in particular may be metallized in parallel by the screen printer 1360, after the metallization of the first solar cell substrate 12 and the second solar cell substrate 14 has been performed.

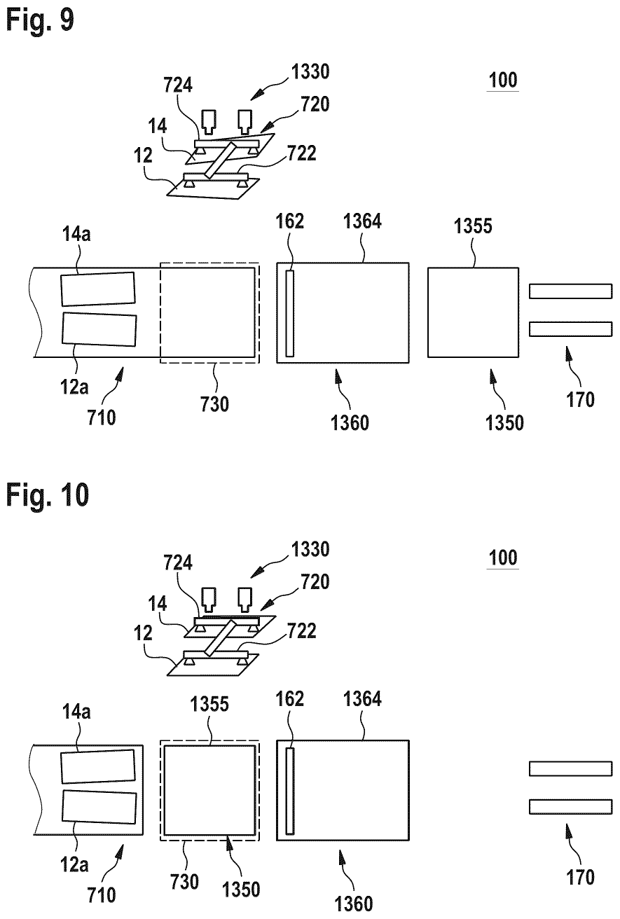

The linear tool 100 may include an alignment system 720. The alignment system 720 is a possible example of the alignment system 1320 shown in FIG. 13. The alignment system 720 may include a gripper system for picking up the first solar cell substrate 12 and the second solar cell substrate 14 from the transportation system 710 when the first solar cell substrate 12 and the second solar cell substrate 14 are in the transfer area 730. The gripper system may include a first gripper section 722 for holding the first solar cell substrate 12 and a second gripper section 724 for holding the second solar cell substrate 14. FIG. 8 shows the first solar cell substrate 12 and the second solar cell substrate 14 supported by the transportation system 710 in the transfer area 730, before the first solar cell substrate 12 and the second solar cell substrate 14 are picked up by the gripper system of the alignment system 720. FIG. 9 shows the first solar cell substrate 12 and the second solar cell substrate 14 being held by the gripper system, after the first solar cell substrate 12 and the second solar cell substrate 14 have been picked up in the transfer area 730 by the gripper system. The first solar cell substrate 12 and the second solar cell substrate 14 are held by the first gripper section 722 and the second gripper section 724, respectively.

The alignment system 720 of the linear tool 100 of FIGS. 7-12, being a gripper-based system, is distinguished from the alignment system 120 of the linear tool 100 of FIGS. 1-6, being a platform-based system. A gripper system, such as the gripper system of the alignment system 720, can be (part of) a pick and place system. A gripper system can be configured to hold the first solar cell substrate 12 and the second solar cell substrate 14 at a top surface of the first solar cell substrate 12 and the second solar cell substrate 14. The gripper system may engage the first solar cell substrate 12 and the second solar cell substrate 14 from above, e.g. by one or more suction cups disposed above the first solar cell substrate 12 and the second solar cell substrate 14.

The gripper system of the alignment system 720 may include precisely two gripper sections being the first gripper section 722 and the second gripper section 724. The two gripper sections may each be configured for holding a half-cut solar cell substrate, so that precisely two half-cut solar cell substrates, which have a joint area corresponding to the area of one full solar cell, are held by the alignment system 720.

The gripper system of the alignment system 720 may be movable in a vertical direction to pick up solar cell substrates, e.g. the first solar cell substrate 12 and the second solar cell substrate 14, from the transfer area 730 and to place the solar cell substrates into the transfer area 730. It may be the case that the gripper system is stationary in a horizontal sense. The gripper system may be disposed above the transfer area 730 and may be movable in a vertical direction only.

When the first solar cell substrate 12 and the second solar cell substrate 14 are supported by the transportation system 710 in the transfer area 730 (as shown in FIG. 8), a misalignment of the first solar cell substrate 12 and/or the second solar cell substrate 14 may exist. In light thereof, when the first solar cell substrate 12 and the second solar cell substrate 14 are initially held by the gripper system of the alignment system 720 (as shown in FIG. 9), a misalignment may be present. A relative position of the first gripper section 722 and the second gripper section 724 may be adjustable to adjust the relative position of the first solar cell substrate 12 and the second solar cell substrate 14, in particular to bring the first solar cell substrate 12 and the second solar cell substrate 14 in an aligned configuration.

At least one of the first gripper section 722 and the second gripper section 724 may be movable to adjust a relative position of the first solar cell substrate 12 held by the first gripper section 722 and the second solar cell substrate 14 held by the second gripper section 724. The alignment system 720 may include an actuator system including one or more actuators, e.g. one or more motors, for moving at least one of the first gripper section 722 and the second gripper section 724. The alignment system 720 may be controlled by the controller.

The first gripper section 722 may be movable in at least one of a first horizontal direction, a second horizontal direction different from (e.g. perpendicular to) the first horizontal direction, and an angular direction. The movement in an angular direction may include an angular movement with respect to a rotation axis perpendicular to a receiving surface of the first gripper section 722. By performing one or more of the aforementioned movements, the first gripper section 722 may adjust a position of the first solar cell substrate 12. The first gripper section 722 may be movable according to one or more of the aforementioned movements relative to the second gripper section 724 to adjust a relative position of the first solar cell substrate 12 with respect to the second solar cell substrate 14. The first gripper section 722 may be individually movable, independently of the second gripper section 724.

Additionally, or alternatively, the second gripper section 724 may be movable in at least one of a first horizontal direction, a second horizontal direction different from (e.g. perpendicular to) the first horizontal direction, and an angular direction. Said first direction and/or second horizontal direction may be the same as the first direction and/or second horizontal direction, respectively, described above in relation to the first gripper section 722. The movement in an angular direction may include an angular movement with respect to a rotation axis perpendicular to a receiving surface of the second gripper section 724. By performing one or more of the aforementioned movements, the second gripper section 724 may adjust a position of the second solar cell substrate 14. The second gripper section 724 may be movable according to one or more of the aforementioned movements relative to the first gripper section 722 to adjust a relative position of the second solar cell substrate 14 with respect to the first solar cell substrate 12. The second gripper section 724 may be individually movable, independently of the first gripper section 722.

The first inspection system 1330 may be arranged for inspecting at least one of the first solar cell substrate 12 held by the first gripper section 722 and the second solar cell substrate 14 held by the second gripper section 724. The first inspection system 1330 may be an optical inspection system. The first inspection system 1330 may include one or more cameras. The first inspection system 1330 may be configured to make an image of at least one of the first solar cell substrate 12 held by the first gripper section 722 and the second solar cell substrate 14 held by the second gripper section 724. An alignment of the first solar cell substrate 12 and/or the second solar cell substrate 14 may be performed by the alignment system 720 based on inspection data, e.g. the mentioned image, provided by the first inspection system 1330.

The controller may be connected to the first inspection system 1330. The controller may be connected to the alignment system 720. The controller may instruct the first inspection system 1330 to perform a first inspection of at least one of the first solar cell substrate 12 held by the first gripper section 722 and the second solar cell substrate 14 held by the second gripper section 724. The controller may instruct the alignment system 720 to adjust a relative position of at least one of the first gripper section 722 holding the first solar cell substrate 12 and the second gripper section 724 holding the second solar cell substrate 14 in response to the first inspection.

As illustrated in FIG. 9, after the first solar cell substrate 12 and the second solar cell substrate 14 have been picked up from the transfer area 730 by the gripper system of the alignment system 720, it may be the case that the first solar cell substrate 12 held by the first gripper section 722 and/or the second solar cell substrate 14 held by the second gripper section 724 are misaligned. Based on the inspection performed by the first inspection system 1330, e.g. an image taken by the first inspection system 1330, the alignment system 720 can move at least one of the first gripper section 722 and the second gripper section 724 to provide the first solar cell substrate 12 and the second solar cell substrate 14 in an aligned configuration (with respect to each other, with respect to one or more alignment marks, or the like). An aligned configuration is illustrated in FIG. 10, showing the first solar cell substrate 12 and the second solar cell substrate 14 in an exemplary configuration where the edges thereof are parallel to each other.

As described above, a portion of the transportation system 710 may move the first solar cell substrate 12 and the second solar cell substrate 14 into the transfer area 730. After the first solar cell substrate 12 and the second solar cell substrate 14 have been picked up by the gripper system of the alignment system 720 in the transfer area 730, said portion of the transportation system 710 may be moved out of the transfer area 730, e.g. retracted from the transfer area 730, to vacate the transfer area 730. Said movement of the transportation system 710 out of the transfer area 730 may be performed, for example, during alignment of the first solar cell substrate 12 and the second solar cell substrate 14 by the alignment system 720. The movement of the transportation system 710 may be controlled by the controller.

After the transportation system 710 has vacated the transfer area 730, the shuttle platform 1355 may move into the transfer area 730, more particularly into the loading position of the shuttle platform 1355, which may be in the transfer area 730. The movement of the shuttle platform 1355 may be controlled by the controller. For example, the shuttle platform 1355 may move from the unloading position (e.g. after unloading a previously processed pair of solar cell substrates) to the loading position in the transfer area 730.

At least a portion of the transportation system may be movable out of the transfer area to vacate the transfer area. The shuttle platform may be movable into the loading position in the transfer area that has been vacated by the transportation system.

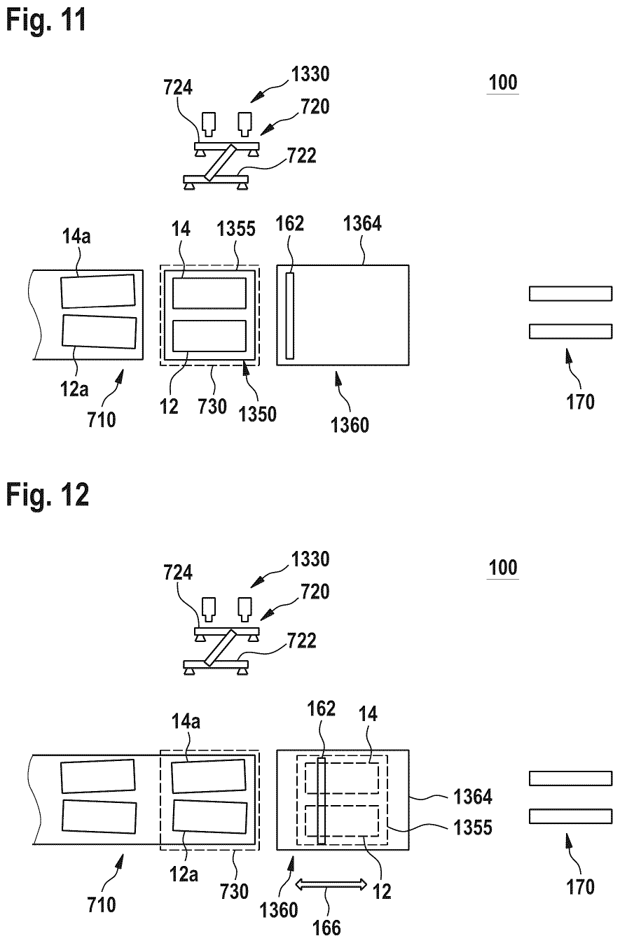

While the shuttle platform 1355 is in the loading position in the transfer area 730, and after the alignment system 720 has provided the first solar cell substrate 12 and the second solar cell substrate 14 in an aligned configuration, the alignment system 720 may place the first solar cell substrate 12 and the second solar cell substrate 14 onto the shuttle platform, as illustrated in FIG. 11. The first solar cell substrate 12 and the second solar cell substrate 14 may be disposed on the shuttle platform in an aligned configuration, as also illustrated in FIG. 11.

After the first solar cell substrate 12 and the second solar cell substrate 14 have been placed onto the shuttle platform 1355 by the alignment system 720, the first inspection system 1330 may optionally perform a second inspection, e.g. when the shuttle platform is in the loading position in the transfer area. The first inspection system 1330 may inspect at least one of the first solar cell substrate 12 and the second solar cell substrate 14 while the first solar cell substrate 12 and the second solar cell substrate 14 are supported by the shuttle platform 1355 in order to detect a potential misalignment of the first solar cell substrate 12 and/or the second solar cell substrate 14. For example, the misalignment may have been introduced during handling of the first solar cell substrate 12 and the second solar cell substrate 14 by the alignment system 720, e.g. while placing the first solar cell substrate 12 and the second solar cell substrate 14 onto the shuttle platform 1355. If a misalignment is detected, the gripper system of the alignment system 720 may pick up the first solar cell substrate 12 and/or the second solar cell substrate 14 from the shuttle platform 1355, move at least one of the first gripper section 722 and the second gripper section 724 to correct the misalignment, and place the first solar cell substrate 12 and/or the second solar cell substrate 14 again onto the shuttle platform 1355. The second inspection and ensuing potential correction of the misalignment may be controlled by the controller.

The possibility of such a correction of a potential misalignment after the solar cell substrates have been placed on the shuttle platform 1355, namely by picking up the first/second solar cell substrate(s) from the shuttle platform 1355 using the gripper system of the alignment system 720, is a particular advantage of the alignment system 720. Said advantage may not be present in the absence of the alignment system 720, and might e.g. not be provided by the linear tool 100 shown in FIGS. 1-6. For example, if in FIG. 4 a second inspection would reveal a misalignment of the solar cell substrates supported by the shuttle platform 1355, in the absence of a gripper based-alignment system like the alignment system 720, it might not be feasible to correct the misalignment, and it may be necessary to discard the misaligned solar cell substrates at that stage, or perform a complicated procedure to move the solar cell substrate back to the alignment system 120.

The controller may be configured to instruct the first inspection system to perform an inspection of at least one of the first solar cell substrate and the second solar cell substrate when the first solar cell substrate and the second solar cell substrate are supported by the shuttle platform, particularly when the first solar cell substrate and the second solar cell substrate are supported by the shuttle platform in the transfer area. If the inspection reveals that a position of at least one of the first solar cell substrate and the second solar cell substrate deviates from a target position (e.g. if a misalignment of the first solar cell substrate and/or the second solar cell substrate is detected), the controller may be configured to instruct the gripper system to pick up at least one of the first solar cell substrate and the second solar cell substrate from the shuttle platform and adjust a position of at least one of the first solar cell substrate and the second solar cell substrate. Said position may be adjusted to align the first solar cell substrate and/or the second solar cell substrate. The controller may be configured to instruct the gripper system to place at least one of the first solar cell substrate and the second solar cell substrate back onto the shuttle platform, so that the first solar cell substrate and the second solar cell substrate are disposed on the shuttle platform in an aligned configuration.

After the first solar cell substrate 12 and the second solar cell substrate 14 have been placed onto the shuttle platform 1355 (with or without the optional second inspection), the shuttle platform 1355 supporting the first solar cell substrate 12 and the second solar cell substrate 14 in an aligned configuration may move from the loading position to the printing position, as illustrated in FIG. 12. The printing position may be outside of the transfer area 730. By moving into the printing position, the shuttle platform 1355 may vacate the transfer area 730. The shuttle platform 1355 may make room for the transportation system 710 to move into the transfer area 730.

The transportation system 710 may move into the transfer area 730 that has been vacated by the shuttle platform 1355 in order to move the third solar cell substrate 12a and the fourth solar cell substrate 14a into the transfer area 730. The third solar cell substrate 12a and the fourth solar cell substrate 14a may be picked up and aligned by the alignment system 720, in the same manner as the first solar cell substrate 12 and the second solar cell substrate 14, while the first solar cell substrate 12 and the second solar cell substrate 14 supported by the shuttle platform 1355 are being metallized by the screen printer 1360.

At least a portion of the transportation system, particularly a portion configured to support a third solar cell substrate and a fourth solar cell substrate, may be configured to be in the transfer area while the shuttle platform is in the printing position.

The shuttle platform may be movable out of the transfer area to vacate the transfer area. At least a portion of the transportation system may be movable into the transfer area that has been vacated by the shuttle platform.

Starting from the configuration shown in FIG. 12, the parallel metallization of the first solar cell substrate 12 and the second solar cell substrate 14, as well as any subsequent operations, are analogous to what was described above with respect to FIGS. 1-6, and the description thereof will not be repeated here.

Apart from the possibility of correcting a potential misalignment of the solar cell substrates after the solar cell substrates have been placed on the shuttle platform 1355 as described above, a further advantage of the linear tool 100 of FIGS. 7-12 (second linear tool) over the linear tool 100 of FIGS. 1-6 (first linear tool) relates to the footprint of the linear too. Specifically, the second linear tool is compacter than the first linear tool since the alignment system 120, which constitutes a processing station between the support 110 and the loading position of the shuttle platform 1355, is not present in the second linear tool. Instead, the second linear tool uses the alignment system 720 being a gripper-based alignment system, which is located above the loading position and does not enlarge the footprint of the linear tool.

A further advantage of the second linear tool is that only one pick and place system is used, namely the gripper system of the alignment system 720. By comparison, in the first linear tool, two pick and place systems are used, namely a first pick and place system for transferring the solar cell substrates from the support 110 to the alignment system 120 and a second pick and place system (the pick and place system 140) for transferring the solar cell substrates from the alignment system 120 to the shuttle platform 1355.

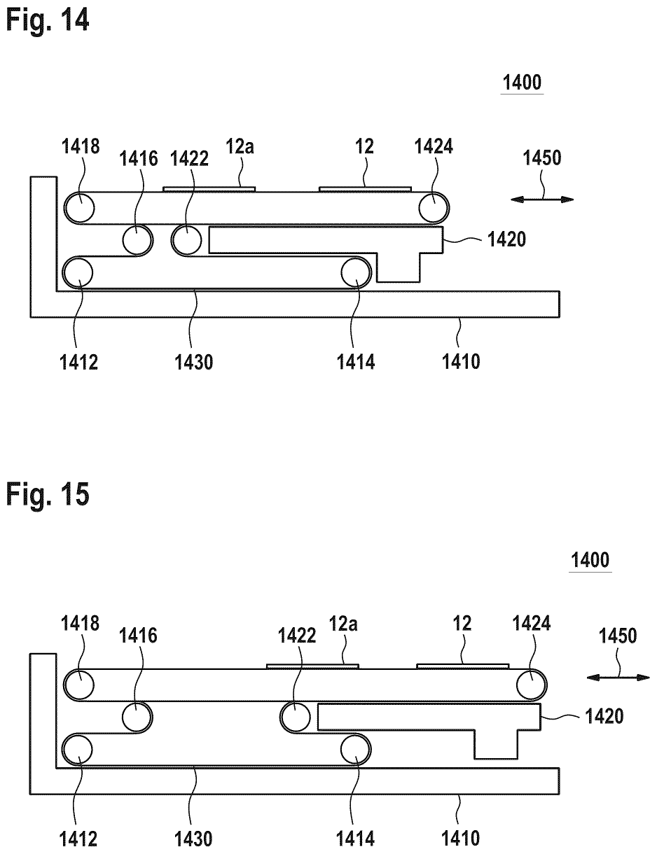

The transportation system 710 may include a telescopic belt conveyer. The telescopic belt conveyer may be extendable to move a portion of the telescopic belt conveyer into the transfer area and retractable to retract the portion of the telescopic belt conveyer out of the transfer area. FIGS. 14-15 show an example of a telescopic belt conveyer 1400.

The telescopic belt conveyer 1400 may include a base 1410 and a movable body 1420 that is movable relative to the base 1410 in a telescopic movement direction 1450. The movable body 1420 may be moved in the telescopic movement direction 1450 using one or more actuators, such as one or more motors, of the telescopic belt conveyer 1400. The base 1410 may be a stationary body, in particular stationary with respect to the telescopic movement direction 1450. The telescopic belt conveyer 1400 may include first pulleys 1412, 1414, 1416 and 1418 that may be mounted to the base 1410. The first pulleys 1412, 1414, 1416 and 1418 may be stationary with respect to the telescopic movement direction 1450. The telescopic belt conveyer 1400 may include second pulleys 1422 and 1424 that may be mounted to the movable body 1420. The second pulleys 1422 and 1424 may move together with the movable body 1420 in the telescopic movement direction 1450. A conveyer belt 1430, e.g. an endless conveyer belt, may be guided by the first pulleys 1412, 1414, 1416 and 1418 and the second pulleys 1422 and 1424. The first solar cell substrate 12 and the second solar cell substrate 14 (the second solar cell substrate 14 is not shown in the side view of FIGS. 14-15) may be transported by the conveyer belt 1430. Behind the first solar cell substrate 12 and the second solar cell substrate 14, a third solar cell substrate 12a and a fourth solar cell substrate 14a (the latter not shown) may be transported by the conveyer belt 1430.

The movable body 1420, together with the second pulleys 1422 and 1424, may move forward in the telescopic movement direction 1450 (e.g. using one or more actuators), as illustrated in FIG. 15, causing the conveyer belt 1430 to extend forward in the telescopic movement direction 1450. In doing so, the first solar cell substrate 12 and the second solar cell substrate 14 may be moved into the transfer area 730 by the telescopic belt conveyer. Conversely, by moving the movable body 1420 backward along the telescopic movement direction 1450, the conveyer belt 1430 may be retracted out of the transfer area 730.

It shall be understood that the particular configuration of pulleys shown in FIGS. 14-15 is one particular example, and that a different number of pulleys and different locations of the pulleys may be considered for providing a telescopic belt conveyer. Further, a telescopic belt conveyer is only one possible example of a transportation system 710, and the transportation system 710 is not limited thereto. For example, instead of a telescopic belt conveyer, the transportation system 710 may include a shuttle system similar to shuttle system 1350, including a shuttle platform that can move into and out of the transfer area 730. Still, a telescopic belt conveyor (as compared to e.g. a second shuttle system) has the advantage of an improved cycle time.

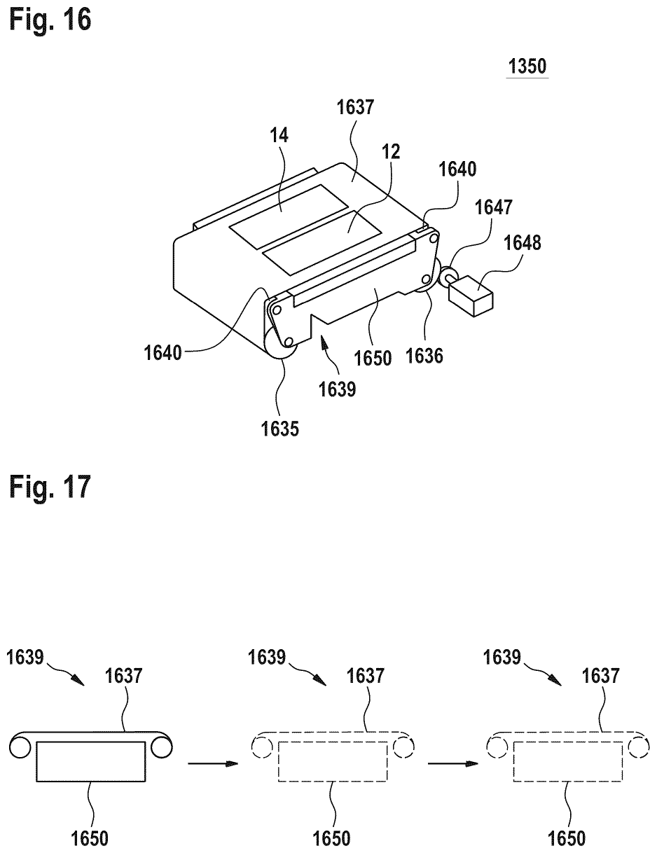

FIG. 16 shows (a portion of) a possible example of a shuttle system 1350, which may be used in any of the linear tools 100 described herein, including the first linear tool and the second linear tool. The shuttle system 1350 may include a conveyer assembly 1639 that may have at least one of a feed spool 1635, a take-up spool 1636, rollers 1640, a conveyer belt 1637 and an actuator 1648. The operation of the actuator 1648 may be controlled by the controller. At least one of the feed spool 1635, take-up spool 1636 and rollers 1640 may be mounted to a shuttle support 1650. The actuator 1648 may be coupled to the feed spool 1635 and/or take-up spool 1636. A set of solar cell substrates, such as the first solar cell substrate 12 and the second solar cell substrate 14, may be supported by the conveyer belt 1637. The receiving surface of the conveyer belt 1637 on which the solar cell substrates are disposed, e.g. the surface between the two rollers 1640, may constitute, in the present example, the shuttle platform 1355.

The conveyer assembly 1639 may be connected to a further actuator (not shown) of the shuttle system 1350 for transporting the conveyer assembly 1639 between the loading position, the printing position and the unloading position as described herein. The conveyer assembly 1639 as a whole, including the feed spool 1635, take-up spool 1636, rollers 1640, conveyer belt 1637 and shuttle support 1650, may be transported, e.g., from the loading position to the printing position, from the printing position to the unloading position, and/or from the unloading position back to the loading position. The transportation movement of the conveyer assembly 1639 is illustrated in FIG. 17, showing the conveyer assembly 1639 consecutively in the loading position (on the left), printing position (middle) and unloading position (on the right). Particularly, the shuttle support 1650 and the conveyer belt 1637 are transported together between the respective positions. The loading position, printing position and unloading position shown in FIG. 17 correspond to the loading/printing/unloading position described with respect to the first linear tool and the second linear tool shown in FIGS. 1-6 and 7-12, respectively.

It may be the case that the conveyer belt 1637 is not an endless belt. The conveyer belt 1637 may be made of a porous material that allows the solar cell substrates to be firmly retained on the conveyer belt 1637, e.g., by applying an underpressure from below the conveyer belt 1637. Specifically, the conveyer belt 1637 may be made of a disposable material, such as paper.

When the conveyer assembly 1639 is in the printing position, the conveyer belt 1637 may be stationary during printing, so that the first solar cell substrate 12 and the second solar cell substrate 14 are also stationary during the metallization thereof.

After the metallization is completed, the conveyer assembly 1639 may move from the printing position to the unloading position. In the unloading position, the shuttle support 1650 may remain stationary and the actuator 1648 may cause a rotation of at least one of the feed spool 1635 and the take-up spool 1636 (e.g. via a drive wheel 1647), resulting in a movement of the conveyer belt 1637 relative to the shuttle support 1650. The movement of the conveyer belt 1637 displaces the first solar cell substrate 12 and the second solar cell substrate 14 with respect to the shuttle support 1650 for unloading the first solar cell substrate 12 and the second solar cell substrate 14 from the conveyer assembly 1639. After the first solar cell substrate 12 and the second solar cell substrate 14 have been unloaded, the conveyer assembly 1639 may move from the unloading position to the loading position for receiving a third solar cell substrate and a fourth solar cell substrate.

The shuttle system may include a shuttle support and a conveyer, e.g. a conveyer belt, carried by the shuttle support. The conveyer may have a receiving surface for receiving the first solar cell substrate and the second solar cell substrate, the receiving surface providing the shuttle platform. The shuttle support and the conveyer carried by the shuttle support may be movable together from the loading position to the printing position and from the printing position to the unloading position. The conveyer may be configured to discharge the first solar cell substrate and the second solar cell substrate from the shuttle system by displacing the receiving surface relative to the shuttle support.

The linear tools 100 described herein involve an alignment system, such as the alignment system 120 or the alignment system 720. Irrespective of which particular alignment system is used, several possible procedures may be applied for aligning the solar cell substrates, as discussed in the following. Each of the procedures in question may be performed under the control of the controller.

A first horizontal direction (“x-direction”, which may correspond to the printing direction 166 described herein, as illustrated in FIG. 5), a second horizontal direction (“y-direction”, which may be perpendicular to the first horizontal direction, e.g. perpendicular to the printing direction 166) and an angular direction (“θ-direction”, which may be a rotation about a vertical axis) may be considered.

The notion of aligning the solar cell substrates (e.g. the first solar cell substrate 12 and the second solar cell substrate 14) may involve an alignment of the solar cell substrates relative to each other (e.g. aligning the long edges of the solar cell substrates to be parallel to each other, aligning the short edges to lie on a common axis so that no off-set exists, etc.), relative to one or more alignment marks (e.g. alignment marks indicating the first horizontal direction, so that the solar cell substrates can be aligned to have long edges that are parallel to the first horizontal direction) and the like.

In one example (“first alignment procedure”), it may be the case that the first alignment platform 122 is individually movable in the first horizontal direction, the second horizontal direction and the angular direction, and that the second alignment platform 124 is also individually movable in the first horizontal direction, the second horizontal direction and the angular direction. By suitably moving the first alignment platform 122 and/or the second alignment platform 124, the first solar cell substrate 12 and the second solar cell substrate 14 may be aligned with respect to the first horizontal direction, the second horizontal direction and the angular direction. In the resulting aligned configuration, the long edges of both solar cell substrates may be parallel to each other and to the first horizontal direction, and it may be the case that there is no offset between the solar cell substrates in the first horizontal direction (see e.g. the aligned configuration of the solar cell substrates in FIG. 3). Thereafter, the first solar cell substrate 12 and the second solar cell substrate 14 may be maintained in the aligned configuration while the first solar cell substrate 12 and the second solar cell substrate 14 are transferred to and supported by the shuttle platform 1355 and during the parallel metallization performed by the screen printer 1360. In the present example, the screen 1364 (which may be part of a print head of the printer) may be a stationary screen that remains in a fixed position. By performing suitable movements of the alignment platforms in the first horizontal direction (“x-direction”), the second horizontal direction (“y-direction”) and/or the angular direction, the alignment system may provide the first solar cell substrate 12 and the second solar cell substrate 14 in an aligned configuration that takes the fixed position of the screen into account. Accordingly, when the shuttle platform 1355 supporting the solar cell substrate 12 and the second solar cell substrate 14 arrives in the printing position, the parallel metallization may be performed without a need to adjust the position of the print head.

In another example (“second alignment procedure”), it may be the case that only one of the first alignment platform 122 and the second alignment platform 124 is individually moved in the first horizontal direction, the second horizontal direction and/or the angular direction. The other one of the first alignment platform 122 and the second alignment platform 124 may be stationary. If, say, the second alignment platform 124 is the stationary one, the first alignment platform 122 may be moved to align the first solar cell substrate 12 with respect to the (stationary) second solar cell substrate 14. In the aligned configuration, the long edges of both solar cell substrates may be parallel to each other, but potentially not parallel to the first horizontal direction. The latter may happen if the second solar cell substrate 14 supported by the second alignment platform 124 has an orientation wherein the long edges of the second solar cell substrate 14 are inclined with respect to the first horizontal direction. In other words, an angular misalignment of the solar cell substrates may remain, so that the alignment provided by the alignment system may only be partial. Thereafter, the first solar cell substrate 12 and the second solar cell substrate 14 may be maintained in the partially aligned configuration while the first solar cell substrate 12 and the second solar cell substrate 14 are transferred to and supported by the shuttle platform 1355 and during the parallel metallization performed by the screen printer 1360. Before performing the metallization, the position of the print head (including the screen 1364) of the screen printer 1360, and accordingly the printing direction 166, may be adjusted at least with respect to the angular direction to compensate for the remaining angular misalignment of the solar cell substrates. In light thereof, it may be the case that, in the printing stroke(s), the squeegee does not move along the first horizontal direction but moves along an inclined printing direction 166 following the long edges of the solar cell substrates. In one example, the shuttle platform 1355 supporting the partially aligned first solar cell substrate 12 and second solar cell substrate 14 in the printing position may be configured to move in a first horizonal direction (“x-direction”) to provide the shuttle platform in a target position with respect to the first horizontal direction. Thereafter, the print head including the screen 1364 may be configured to move in a second horizontal direction (“y-direction”) and/or an angular direction in order to compensate for any remaining misalignment of the solar cell substrates with respect to the second horizontal direction and/or the angular direction. After said movement of the print head, the screen 1364 may be well positioned with respect to the solar cell substrates, and the parallel metallization may be performed.

In another example (“third alignment procedure”), both alignment platforms may be individually movable, like in the first alignment procedure described above. Yet in the present example, the alignment platforms may only be moved in the second horizontal direction and/or the angular direction. As a result, the alignment system may provide the solar cell substrates in a partially aligned configuration wherein the long edges of the solar cell substrates are parallel to each other and to the first horizontal direction, but where an offset may exist between the solar cell substrates with respect to the first horizontal direction (“Δx-offset”, e.g. an offset between the solar cell substrates with respect to the printing direction 166 shown in FIG. 5), since the alignment platforms are not moved in the first horizontal direction. The offset may be compensated by transferring the solar cell substrates one after the other from the alignment system to the shuttle platform 1355 (and not simultaneously, as considered so far), and compensating for the Δx-offset by a suitable movement of the shuttle platform 1355 in the first horizontal direction after the first solar cell substrate 12 has been placed on the shuttle platform 1355 but before the second solar cell substrate 14 has been placed thereon.

Further, the above-described alignment procedures can be combined with each other. For example, the second and third alignment procedure can be combined with each other.

Further, while the above-described examples refer to the platform-based alignment system 120, fully analogous alignment procedures can be performed by the gripper-based alignment system 720. A description thereof is obtained by replacing the first/second alignment platform 122/124 in the above discussion by the first/second gripper section 722/724.

According to a further embodiment, a method for parallel metallization of solar cell substrates is provided. The method includes jointly holding a first solar cell substrate and a second solar cell substrate using an alignment system. The method includes inspecting at least one of the first solar cell substrate and the second solar cell substrate while the first solar cell substrate and the second solar cell substrate are held by the alignment system. The method includes, in response to the inspecting, adjusting a relative position of the first solar cell substrate and the second solar cell substrate using the alignment system. The method includes transferring the first solar cell substrate and the second solar cell substrate from the alignment system to a shuttle platform of a shuttle system when the shuttle platform is in a loading position. The method includes moving the shuttle platform supporting the first solar cell substrate and the second solar cell substrate from the loading position to a printing position. The method includes performing a parallel metallization of the first solar cell substrate and the second solar cell substrate supported by the shuttle platform when the shuttle platform is in the printing position, wherein the parallel metallization is performed by a screen printer. The method includes moving the shuttle platform supporting the first solar cell substrate and the second solar cell substrate from the printing position to an unloading position. The method includes unloading the first solar cell substrate and the second solar cell substrate from the shuttle platform in the unloading position.

The method may include operations corresponding to any function or combination of functions of the linear tools for parallel metallization of solar cell substrates described herein.

As illustrated e.g. by the linear tool 100 shown in FIGS. 1-6, jointly holding the first solar cell substrate and the second solar cell substrate using the alignment system may include supporting the first solar cell substrate using a first alignment platform of the alignment system and supporting the second solar cell substrate using a second alignment platform of the alignment system. The relative position of the first solar cell substrate and the second solar cell substrate may be adjusted by adjusting a relative position of the first alignment platform and the second alignment platform. Inspecting at least one of the first solar cell substrate and the second solar cell substrate while the first solar cell substrate and the second solar cell substrate are held by the alignment system may include inspecting at least one of the first solar cell substrate supported by the first alignment platform and the second solar cell substrate supported by the second alignment platform. The method may include jointly transferring the first solar cell substrate and the second solar cell substrate from the alignment system to the shuttle system using a pick and place system. The pick and place system may place the first solar cell substrate and the second solar cell substrate on the shuttle platform when the shuttle platform is in the loading position.

As illustrated e.g. by the linear tool 100 shown in FIGS. 7-12, the method may include moving the first solar cell substrate and the second solar cell substrate into a transfer area using a transportation system. The method may include picking up the first solar cell substrate and the second solar cell substrate from the transportation system when the first solar cell substrate and the second solar cell substrate are in the transfer area. The first solar cell substrate and the second solar cell substrate may be picked up using a gripper system of the alignment system. Jointly holding the first solar cell substrate and the second solar cell substrate using the alignment system may include holding the first solar cell substrate using a first gripper section of the gripper system and holding the second solar cell substrate using a second gripper section of the gripper system. The relative position of the first solar cell substrate and the second solar cell substrate may be adjusted by adjusting a relative position of the first gripper section and the second gripper section. Inspecting at least one of the first solar cell substrate and the second solar cell substrate while the first solar cell substrate and the second solar cell substrate are held by the alignment system may include inspecting at least one of the first solar cell substrate held by the first gripper section and the second solar cell substrate held by the second gripper section. The loading position of the shuttle platform may be in the transfer area. The method may include placing the first solar cell substrate and the second solar cell substrate on the shuttle platform using the gripper system when the shuttle platform is in the loading position in the transfer area.

The following Embodiments 1 through 15 also form part of the present disclosure:

Embodiment 1. A linear tool (100) for parallel metallization of solar cell substrates, comprising:
an alignment system (1320, 120, 720) for jointly holding a first solar cell substrate (12) and a second solar cell substrate (14) and for adjusting a relative position of the first solar cell substrate and the second solar cell substrate;
a first inspection system (1330) arranged for inspecting at least one of the first solar cell substrate and the second solar cell substrate while the first solar cell substrate and the second solar cell substrate are held by the alignment system;
a shuttle system (1350) comprising a shuttle platform (1355) for jointly supporting the first solar cell substrate and the second solar cell substrate, the shuttle platform being movable from a loading position to a printing position, the linear tool being configured to transfer the first solar cell substrate and the second solar cell substrate from the alignment system to the shuttle platform when the shuttle platform is in the loading position; and
a screen printer (1360) comprising a screen (1364) facing the shuttle platform when the shuttle platform is in the printing position, the screen printer being configured for parallel metallization of the first solar cell substrate and the second solar cell substrate supported by the shuttle platform when the shuttle platform is in the printing position,
the shuttle platform being movable from the printing position to an unloading position for unloading the first solar cell substrate and the second solar cell substrate from the shuttle platform.
   Embodiment 2. The linear tool of Embodiment 1, further comprising:
a transportation system (710) for jointly transporting the first solar cell substrate and the second solar cell substrate, the transportation system arranged to move the first solar cell substrate and the second solar cell substrate into a transfer area (730),
the alignment system comprising a gripper system for picking up the first solar cell substrate and the second solar cell substrate from the transportation system when the first solar cell substrate and the second solar cell substrate are in the transfer area, the gripper system including a first gripper section (722) for holding the first solar cell substrate and a second gripper section (724) for holding the second solar cell substrate, a relative position of the first gripper section and the second gripper section being adjustable to adjust the relative position of the first solar cell substrate and the second solar cell substrate,
the first inspection system being arranged for inspecting at least one of the first solar cell substrate held by the first gripper section and the second solar cell substrate held by the second gripper section,
the loading position of the shuttle platform being in the transfer area,
the gripper system being arranged for placing the first solar cell substrate and the second solar cell substrate on the shuttle platform when the shuttle platform is in the loading position in the transfer area.
   Embodiment 3. The linear tool of Embodiment 2, wherein at least one of the following (a) and (b) holds:
(a) at least a portion of the transportation system is movable out of the transfer area to vacate the transfer area, and the shuttle platform is movable into the loading position in the transfer area that has been vacated by the transportation system; and
(b) the shuttle platform is movable out of the transfer area to vacate the transfer area, and at least a portion of the transportation system is movable into the transfer area that has been vacated by the shuttle platform.
   Embodiment 4. The linear tool of Embodiment 2 or 3, wherein at least a portion of the transportation system, particularly a portion configured to support the first solar cell substrate and the second solar cell substrate, is configured to be in the transfer area while the shuttle platform is in the printing position.
   Embodiment 5. The linear tool of any of Embodiments 2 to 4, wherein the transportation system includes a telescopic belt conveyer (1400), the telescopic belt conveyer being extendable to move a portion of the telescopic belt conveyer into the transfer area and retractable to retract the portion of the telescopic belt conveyer out of the transfer area.
   Embodiment 6. The linear tool of any of Embodiments 2 to 5, further comprising a controller configured to instruct the first inspection system to perform an inspection of at least one of the first solar cell substrate and the second solar cell substrate when the first solar cell substrate and the second solar cell substrate are supported by the shuttle platform,
particularly wherein, if the inspection reveals that a position of at least one of the first solar cell substrate and the second solar cell substrate deviates from a target position, the controller is configured to instruct the gripper system to pick up at least one of the first solar cell substrate and the second solar cell substrate from the shuttle platform and adjust a position of at least one of the first solar cell substrate and the second solar cell substrate.
   Embodiment 7. The linear tool of Embodiment 1,
wherein the alignment system comprises a first alignment platform (122) for supporting the first solar cell substrate and a second alignment platform (124) for supporting the second solar cell substrate, a relative position of the first alignment platform and the second alignment platform being adjustable to adjust the relative position of the first solar cell substrate and the second solar cell substrate,
the first inspection system being arranged for inspecting at least one of the first solar cell substrate supported by the first alignment platform and the second solar cell substrate supported by the second alignment platform,
the linear tool further comprising a pick and place system (140) arranged for jointly transferring the first solar cell substrate and the second solar cell substrate from the alignment system to the shuttle system, the pick and place system being arranged for placing the first solar cell substrate and the second solar cell substrate on the shuttle platform when the shuttle platform is in the loading position.
   Embodiment 8. The linear tool of Embodiment 7, wherein the alignment system comprises precisely two alignment platforms being the first alignment platform and the second alignment platform.
   Embodiment 9. The linear tool of Embodiment 7 or 8, wherein the first alignment platform has a first receiving area for receiving the first solar cell substrate and the second alignment platform has a second receiving area for receiving the second solar cell substrate,
the first receiving area having a first length and a first width, the first width being about one half of the first length,
the second receiving area having a second length and a second width, the second width being about one half of the second length.
   Embodiment 10. The linear tool of any of Embodiments 7 to 9, further comprising a second inspection system (135) arranged for inspecting at least one of the first solar cell substrate and the second solar cell substrate supported by the shuttle platform, particularly when the shuttle platform is in the loading position.
   Embodiment 11. The linear tool of any of the preceding Embodiments, wherein the screen printer defines a printing direction (166) for performing the parallel metallization of the first solar cell substrate and the second solar cell substrate, the printing direction corresponding to a length direction of the first solar cell substrate and the second solar cell substrate supported by the shuttle platform in the printing position.
   Embodiment 12. The linear tool of any of the preceding Embodiments, wherein the shuttle system includes a shuttle support (1650) and a conveyer (1637) carried by the shuttle support,
the conveyer having a receiving surface for receiving the first solar cell substrate and the second solar cell substrate, the receiving surface providing the shuttle platform,
the shuttle support and the conveyer carried by the shuttle support being movable together from the loading position to the printing position and from the printing position to the unloading position,
the conveyer being configured to discharge the first solar cell substrate and the second solar cell substrate from the shuttle system by displacing the receiving surface relative to the shuttle support.
   Embodiment 13. A method for parallel metallization of solar cell substrates, comprising:
jointly holding a first solar cell substrate (12) and a second solar cell substrate (14) using an alignment system (1320, 120, 720);
inspecting at least one of the first solar cell substrate and the second solar cell substrate while the first solar cell substrate and the second solar cell substrate are held by the alignment system;
in response to the inspecting, adjusting a relative position of the first solar cell substrate and the second solar cell substrate using the alignment system;
transferring the first solar cell substrate and the second solar cell substrate from the alignment system to a shuttle platform (1355) of a shuttle system (1350) when the shuttle platform is in a loading position;
moving the shuttle platform supporting the first solar cell substrate and the second solar cell substrate from the loading position to a printing position;
performing a parallel metallization of the first solar cell substrate and the second solar cell substrate supported by the shuttle platform when the shuttle platform is in the printing position, wherein the parallel metallization is performed by a screen printer (1360);
moving the shuttle platform supporting the first solar cell substrate and the second solar cell substrate from the printing position to an unloading position; and
unloading the first solar cell substrate and the second solar cell substrate from the shuttle platform in the unloading position.
   Embodiment 14. The method of Embodiment 13, further comprising:
moving the first solar cell substrate and the second solar cell substrate into a transfer area (730) using a transportation system (710); and
picking up the first solar cell substrate and the second solar cell substrate from the transportation system when the first solar cell substrate and the second solar cell substrate are in the transfer area, wherein the first solar cell substrate and the second solar cell substrate are picked up using a gripper system of the alignment system,
wherein jointly holding the first solar cell substrate and the second solar cell substrate using the alignment system includes holding the first solar cell substrate using a first gripper section (722) of the gripper system and holding the second solar cell substrate using a second gripper section (724) of the gripper system,
wherein the relative position of the first solar cell substrate and the second solar cell substrate is adjusted by adjusting a relative position of the first gripper section and the second gripper section,
wherein inspecting at least one of the first solar cell substrate and the second solar cell substrate while the first solar cell substrate and the second solar cell substrate are held by the alignment system includes inspecting at least one of the first solar cell substrate held by the first gripper section and the second solar cell substrate held by the second gripper section,
the loading position of the shuttle platform being in the transfer area, the method further comprising:
placing the first solar cell substrate and the second solar cell substrate on the shuttle platform using the gripper system when the shuttle platform is in the loading position in the transfer area.
   Embodiment 15. The method of Embodiment 13,
wherein jointly holding the first solar cell substrate and the second solar cell substrate using the alignment system includes supporting the first solar cell substrate using a first alignment platform (122) of the alignment system and supporting the second solar cell substrate using a second alignment platform (124) of the alignment system,
wherein the relative position of the first solar cell substrate and the second solar cell substrate is adjusted by adjusting a relative position of the first alignment platform and the second alignment platform,
wherein inspecting at least one of the first solar cell substrate and the second solar cell substrate while the first solar cell substrate and the second solar cell substrate are held by the alignment system includes inspecting at least one of the first solar cell substrate supported by the first alignment platform and the second solar cell substrate supported by the second alignment platform,
the method further comprising:
jointly transferring the first solar cell substrate and the second solar cell substrate from the alignment system to the shuttle system using a pick and place system (140), wherein the pick and place system places the first solar cell substrate and the second solar cell substrate on the shuttle platform when the shuttle platform is in the loading position.

While the foregoing is directed to embodiments of the disclosure, other and further embodiments of the disclosure may be devised without departing from the basic scope thereof, and the scope thereof is determined by the claims that follow.

What is claimed is:

1. A linear tool (100) for parallel metallization of solar cell substrates, comprising:
an alignment system (1320, 120, 720) for jointly holding a first solar cell substrate (12) and a second solar cell substrate (14) and for adjusting a relative position of the first solar cell substrate and the second solar cell substrate;
a first inspection system (1330) arranged for inspecting at least one of the first solar cell substrate and the second solar cell substrate while the first solar cell substrate and the second solar cell substrate are held by the alignment system;
a shuttle system (1350) comprising a shuttle platform (1355) for jointly supporting the first solar cell substrate and the second solar cell substrate, the shuttle platform being movable from a loading position to a printing position, the linear tool being configured to transfer the first solar cell substrate and the second solar cell substrate from the alignment system to the shuttle platform when the shuttle platform is in the loading position; and
a screen printer (1360) comprising a screen (1364) facing the shuttle platform when the shuttle platform is in the printing position, the screen printer being configured for parallel metallization of the first solar cell substrate and the second solar cell substrate supported by the shuttle platform when the shuttle platform is in the printing position,
the shuttle platform being movable from the printing position to an unloading position for unloading the first solar cell substrate and the second solar cell substrate from the shuttle platform.

2. The linear tool of claim 1, further comprising:
a transportation system (710) for jointly transporting the first solar cell substrate and the second solar cell substrate, the transportation system arranged to move the first solar cell substrate and the second solar cell substrate into a transfer area (730),
the alignment system comprising a gripper system for picking up the first solar cell substrate and the second solar cell substrate from the transportation system when the first solar cell substrate and the second solar cell substrate are in the transfer area, the gripper system including a first gripper section (722) for holding the first solar cell substrate and a second gripper section (724) for holding the second solar cell substrate, a relative position of the first gripper section and the second gripper section being adjustable to adjust the relative position of the first solar cell substrate and the second solar cell substrate,
the first inspection system being arranged for inspecting at least one of the first solar cell substrate held by the first gripper section and the second solar cell substrate held by the second gripper section,
the loading position of the shuttle platform being in the transfer area,
the gripper system being arranged for placing the first solar cell substrate and the second solar cell substrate on the shuttle platform when the shuttle platform is in the loading position in the transfer area.

3. The linear tool of claim 2, wherein at least one of the following (a) and (b) holds:
(a) at least a portion of the transportation system is movable out of the transfer area to vacate the transfer area, and the shuttle platform is movable into the loading position in the transfer area that has been vacated by the transportation system; and
(b) the shuttle platform is movable out of the transfer area to vacate the transfer area, and at least a portion of the transportation system is movable into the transfer area that has been vacated by the shuttle platform.

4. The linear tool of claim 2, wherein at least a portion of the transportation system is configured to be in the transfer area while the shuttle platform is in the printing position.

5. The linear tool of claim 2, wherein at least a portion of the transportation system configured to support the first solar cell substrate and the second solar cell substrate is configured to be in the transfer area while the shuttle platform is in the printing position.

6. The linear tool of claim 2, wherein the transportation system includes a telescopic belt conveyer (1400), the telescopic belt conveyer being extendable to move a portion of the telescopic belt conveyer into the transfer area and retractable to retract the portion of the telescopic belt conveyer out of the transfer area.

7. The linear tool of claim 2, further comprising a controller configured to instruct the first inspection system to perform an inspection of at least one of the first solar cell substrate and the second solar cell substrate when the first solar cell substrate and the second solar cell substrate are supported by the shuttle platform.

8. The linear tool of claim 7, wherein, if the inspection reveals that a position of at least one of the first solar cell substrate and the second solar cell substrate deviates from a target position, the controller is configured to instruct the gripper system to pick up at least one of the first solar cell substrate and the second solar cell substrate from the shuttle platform and adjust a position of at least one of the first solar cell substrate and the second solar cell substrate.

9. The linear tool of claim 1,
wherein the alignment system comprises a first alignment platform (122) for supporting the first solar cell substrate and a second alignment platform (124) for supporting the second solar cell substrate, a relative position of the first alignment platform and the second alignment platform being adjustable to adjust the relative position of the first solar cell substrate and the second solar cell substrate,
the first inspection system being arranged for inspecting at least one of the first solar cell substrate supported by the first alignment platform and the second solar cell substrate supported by the second alignment platform,
the linear tool further comprising a pick and place system (140) arranged for jointly transferring the first solar cell substrate and the second solar cell substrate from the alignment system to the shuttle system, the pick and place system being arranged for placing the first solar cell substrate and the second solar cell substrate on the shuttle platform when the shuttle platform is in the loading position.

10. The linear tool of claim 9, wherein the alignment system comprises precisely two alignment platforms being the first alignment platform and the second alignment platform.

11. The linear tool of claim 9, wherein the first alignment platform has a first receiving area for receiving the first solar cell substrate and the second alignment platform has a second receiving area for receiving the second solar cell substrate,
the first receiving area having a first length and a first width, the first width being about one half of the first length,
the second receiving area having a second length and a second width, the second width being about one half of the second length.

12. The linear tool of claim 9, further comprising a second inspection system (135) arranged for inspecting at least one of the first solar cell substrate and the second solar cell substrate supported by the shuttle platform.

13. The linear tool of claim 12, wherein the second inspection system is arranged for inspecting at least one of the first solar cell substrate and the second solar cell substrate supported by the shuttle platform when the shuttle platform is in the loading position.

14. The linear tool of claim 1, wherein the screen printer defines a printing direction (166) for performing the parallel metallization of the first solar cell substrate and the second solar cell substrate, the printing direction corresponding to a length direction of the first solar cell substrate and the second solar cell substrate supported by the shuttle platform in the printing position.

15. The linear tool of claim 1, wherein the shuttle system includes a shuttle support (1650) and a conveyer (1637) carried by the shuttle support,
the conveyer having a receiving surface for receiving the first solar cell substrate and the second solar cell substrate, the receiving surface providing the shuttle platform,
the shuttle support and the conveyer carried by the shuttle support being movable together from the loading position to the printing position and from the printing position to the unloading position,
the conveyer being configured to discharge the first solar cell substrate and the second solar cell substrate from the shuttle system by displacing the receiving surface relative to the shuttle support.

16. A method for parallel metallization of solar cell substrates, comprising:
jointly holding a first solar cell substrate (12) and a second solar cell substrate (14) using an alignment system (1320, 120, 720);
inspecting at least one of the first solar cell substrate and the second solar cell substrate while the first solar cell substrate and the second solar cell substrate are held by the alignment system;
in response to the inspecting, adjusting a relative position of the first solar cell substrate and the second solar cell substrate using the alignment system;
transferring the first solar cell substrate and the second solar cell substrate from the alignment system to a shuttle platform (1355) of a shuttle system (1350) when the shuttle platform is in a loading position;
moving the shuttle platform supporting the first solar cell substrate and the second solar cell substrate from the loading position to a printing position;
performing a parallel metallization of the first solar cell substrate and the second solar cell substrate supported by the shuttle platform when the shuttle platform is in the printing position, wherein the parallel metallization is performed by a screen printer (1360);
moving the shuttle platform supporting the first solar cell substrate and the second solar cell substrate from the printing position to an unloading position; and
unloading the first solar cell substrate and the second solar cell substrate from the shuttle platform in the unloading position.

17. The method of claim 16, further comprising:
moving the first solar cell substrate and the second solar cell substrate into a transfer area (730) using a transportation system (710); and
picking up the first solar cell substrate and the second solar cell substrate from the transportation system when the first solar cell substrate and the second solar cell substrate are in the transfer area, wherein the first solar cell substrate and the second solar cell substrate are picked up using a gripper system of the alignment system,
wherein jointly holding the first solar cell substrate and the second solar cell substrate using the alignment system includes holding the first solar cell substrate using a first gripper section (722) of the gripper system and holding the second solar cell substrate using a second gripper section (724) of the gripper system,
wherein the relative position of the first solar cell substrate and the second solar cell substrate is adjusted by adjusting a relative position of the first gripper section and the second gripper section,
wherein inspecting at least one of the first solar cell substrate and the second solar cell substrate while the first solar cell substrate and the second solar cell substrate are held by the alignment system includes inspecting at least one of the first solar cell substrate held by the first gripper section and the second solar cell substrate held by the second gripper section,
the loading position of the shuttle platform being in the transfer area, the method further comprising:
placing the first solar cell substrate and the second solar cell substrate on the shuttle platform using the gripper system when the shuttle platform is in the loading position in the transfer area.

18. The method of claim 17, further comprising at least one of the following (a) and (b):
(a) moving at least a portion of the transportation system out of the transfer area to vacate the transfer area; and moving the shuttle platform into the loading position in the transfer area that has been vacated by the transportation system; and
(b) moving the shuttle platform out of the transfer area to vacate the transfer area; and moving at least a portion of the transportation system into the transfer area that has been vacated by the shuttle platform.

19. The method of claim 16,
wherein jointly holding the first solar cell substrate and the second solar cell substrate using the alignment system includes supporting the first solar cell substrate using a first alignment platform (122) of the alignment system and supporting the second solar cell substrate using a second alignment platform (124) of the alignment system,
wherein the relative position of the first solar cell substrate and the second solar cell substrate is adjusted by adjusting a relative position of the first alignment platform and the second alignment platform,
wherein inspecting at least one of the first solar cell substrate and the second solar cell substrate while the first solar cell substrate and the second solar cell substrate are held by the alignment system includes inspecting at least one of the first solar cell substrate supported by the first alignment platform and the second solar cell substrate supported by the second alignment platform,
the method further comprising:
jointly transferring the first solar cell substrate and the second solar cell substrate from the alignment system to the shuttle system using a pick and place system (140), wherein the pick and place system places the first solar cell substrate and the second solar cell substrate on the shuttle platform when the shuttle platform is in the loading position.

20. The method of claim 19, wherein the alignment system comprises precisely two alignment platforms being the first alignment platform and the second alignment platform.
